(19) United States
(12) Patent Application Publication
(10) Pub. No.: US 2021/0305138 A1
(43) Pub. Date: Sep. 30, 2021

(54) PACKAGE LAND PAD IN CLOSED-LOOP TRACE FOR HIGH SPEED DATA SIGNALING

(71) Applicant: Intel Corporation, Santa Clara, CA (US)

(72) Inventors: Zhichao ZHANG, Chandler, AZ (US); Zhenguo JIANG, Chandler, AZ (US); Haifa HARIRI, Phoenix, AZ (US); Kemal AYGÜN, Tempe, AZ (US); Sriram SRINIVASAN, Chandler, AZ (US)

(21) Appl. No.: 16/828,466

(22) Filed: Mar. 24, 2020

(51) Int. Cl. H01L 23/498; H01R 12/71

(52) U.S. Cl. CPC H01L 23/49811; H01R 12/712

(57) ABSTRACT

Embodiments disclosed herein include electronic packaged assemblies. In an embodiment, an electronic package comprises first and second surfaces. The second surface has a land pad in a land pad opening. The land pad is spaced away from the land pad opening by an outer gap. The land pad is a closed loop. In an embodiment, the electronic package is electrically coupled to a socket. The socket has an interconnect with a first connector and a second connector. The first connector of the interconnect is directly coupled to at least one portion of the closed loop. In an embodiment, when the first connector is coupled to at least two or more portions of the closed loop, the portions are spaced away from each other by a portion of the inner or outer gap. The closed loop comprises a conductive line continuously extending from a first end to a second end.

### TECHNICAL FIELD

Embodiments of the present disclosure relate to semiconductor devices, and more particularly to a semiconductor package having a base layer that includes land pads with closed-loop conductive lines.

### BACKGROUND

The demand for miniaturization of form factor and increased levels of integration for high performance are driving sophisticated packaging approaches in the semiconductor industry. One such approach is to use microelectronic packages to enable miniaturization of small form factor and high performance. Such architectures generally depend on land grid array (LGA) sockets to couple electronic packages to boards. The LGA sockets have various interconnects and land pads coupled together to form channels that communicate data between the packages and boards.

LGA sockets are one the major contributors to the data transfer rates associated with peripheral component interconnect express (PCIe) and double data rate (DDR) channels. The data rates for PCIe and DDR channels are constantly increasing and have typically doubled for each transitioning generation. Newer generations of PCIe and DDR channels demand broader channel bandwidth. As such, LGA sockets have their own integration challenges. One such challenge is that the land pads present a lumped capacitance (C) effect. Another challenge is that the interconnects similarly suffer from a lumped inductive (L) effect. Accordingly, such challenges cause the LGA socket to have series LC connections that increase reflection/loss, form resonance, and limit the bandwidth of the PCIe and DDR channels.

Reducing the LGA land pad size has been proposed to reduce the lumped C effect and mitigate the challenges associated with the series LC connections. However, land pad size reduction reduces the effective contact area, increases the challenges for constructing reliable mechanical connections, and requires more complicated dimension tolerances and alignment techniques. Also, aggressive voiding around the pads or in the pads has been proposed to reduce the lumped C effect. However, aggressive voidance reduces the routing space in the package layers above the pads, increases the package layer count/costs, and increases substrate mechanical reliability risks. Accordingly, land pad size reductions and aggressive voidance around the pads negate the benefits of the LGA socket—and are not desirable solutions.

### BRIEF DESCRIPTION OF THE DRAWINGS

FIG. 1 is a plan illustration of an electronic package with a surface that has a land grid array (LGA) land pad opening and a LGA land pad, where the LGA land pad is implemented with a closed loop, in accordance with an embodiment.

FIG. 2 is a plan illustration of an electronic packaged assembly having a socket and an electronic package with a surface that has a plurality of LGA land pad openings and a plurality of LGA land pads, where the plurality of LGA land pads comprise a differential pair of closed loops, in accordance with an embodiment.

FIG. 3 is a cross-sectional illustration of an electronic packaged assembly with an electronic package, a socket, and a board, where the electronic package has a surface that has a plurality of LGA land pads that are implemented with a plurality of closed loops, in accordance with an embodiment.

FIGS. 4A-4C are plan illustrations of electronic packages with LGA land pads implemented with closed loops that have different socket contact locations, in accordance with some embodiments.

FIG. 5 is a cross-sectional illustration of an electronic packaged assembly with an integrated circuit (IC) die, a substrate, an electronic package, a socket, and a board, where the electronic package has a surface with a plurality of LGA land pads that are implemented with a plurality of closed loops, in accordance with an embodiment.

FIG. 6 is a schematic of a computing device with an electronic package having a surface with a plurality of LGA land pads that are implemented with a plurality of closed loops, in accordance with an embodiment.

### EMBODIMENTS OF THE DETAILED DESCRIPTION

Described herein are electronic packages with a base layer that includes land grid array (LGA) land pads with closed-loop transmission lines, in accordance with various embodiments. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

As noted above, electronic package architectures are limited, at least in part, by the sockets generally used to couple the dies, electronic packages, and/or boards together. For example, newer generations of peripheral component interconnect express (PCIe) and double data rate (DDR) channels in the sockets require broader channel bandwidths to effectively communicate data between the electronic package architectures. Such sockets have LGA land pads that present a lumped C effect which is in series with a lumped inductive effect from the socket pins themselves. These series LC connections formed in the sockets can therefore cause increased reflection/loss, resonance issues, and limited channel bandwidths.

Additionally, as noted above, the LGA land pads suffer from the lumped C effect due to the large pad size. The lumped C effect can be reduced by shrinking the size (or area) of the land pads. However, pad size reduction is substantially limited in order to have reliable and broader channel bandwidth connections in the sockets, because the size of the pads cannot be smaller than the existing envelope contact area of the respective pads. As such, pad size reductions negatively impact the demand for broader channel bandwidths, negating the benefits of implementing an LGA socket.

Accordingly, embodiments disclosed herein include an electronic package with a base layer that has a plurality of pads with closed-loop transmission lines. The electronic packages disclosed below replace the existing solid LGA land pads with closed-loop transmission lines (or traces) to thereby convert the lumped C effect to transmission line behavior-type properties. As such, the embodiments described herein provide pads in the form of closed-loop transmission lines that replace the conventional solid land pads without experiencing the challenges of the LGA sockets disclosed above.

The use of such transmission lines of the base layer of the electronic packages allow for the benefits of the electronic packaged assemblies to be realized by removing the LGA land pad lumped capacitance effect without also significantly reducing the need for socket pad size reductions and/or aggressive package voiding. That is, package land pads in accordance with the embodiments disclosed herein provide closed-loop transmission lines for high speed data signaling that enable suppressing the lumped C effects and increasing the scale up of the channel speeds/bandwidths. Particularly, the closed-loop transmission lines effectively reduce the parasitic capacitance from the package pads to improve the component/channel reflection and loss in order to support speed scaling for, for example, PCIe and DDR channels. Additionally, the transmission lines also enable relaxing the requirements on pad physical size reductions and package voiding above the pads. Such closed-loop transmission lines further free-up design space in the electronic packages and avoid costly tolerance and alignment control needs, while the existing package design rules may be used to form the closed-loop transmission lines.

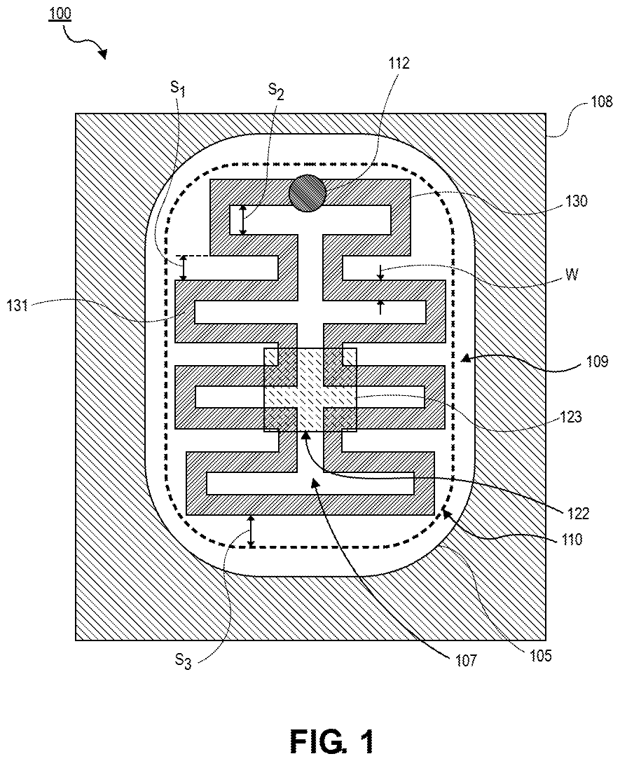

Referring now to FIG. 1, a cross-sectional illustration of an electronic package 100 is shown, in accordance with an embodiment. In an embodiment, the electronic package 100 comprises a base layer 108. The base layer 108 serves as a conductive layer that has a land pad opening 105 and a land pad 130. In an embodiment, the base layer 108 may be a bottom surface or one of the bottommost surfaces. For example, the base layer 108 may be positioned directly above a top surface of a socket. In one embodiment, the base layer 108 may be a ground plane with the land pad opening 105 fully surrounding the land pad 130. The land pad opening 105 allows the land pad 130 to be electrically isolated from the base layer 108. For example, the land pad opening 105 may be spaced away from the land pad 130 by an outer gap 109.

The outer gap 109 may serve as a non-uniform spacing between the land pad opening 105 and an outer perimeter of the land pad 130. That is, the outer gap 109 may have one or more different widths that are measured between the land pad opening 105 and one or more different portions of the outer perimeter of the land pad 130. In one embodiment, the outer gap 109 may be filled with a dielectric material. For example, the dielectric layer may be a buildup film, a photo-imageable dielectric (PID), an epoxy molding material, a solder resist material, or any other dielectric material. The dielectric material may be disposed in the outer gap 109 to form a surface of the dielectric material that may be substantially coplanar with a surface of the land pad 130 (e.g., an exposed surface of the land pad 130).

In some embodiments, the land pad 130 may be any electrical contact pad that provides an electrical connection between the base layer 108 of the electronic package 100 and an interconnect 123. In an embodiment, the interconnect 123 may be any type of socket interconnect such as pins or the like. For example, the interconnect 123 may be a socket pin.

As noted above, in an embodiment, the land pad 130 may have an exposed surface that defines a footprint of the land pad 130. In an embodiment, the land pad 130 may have one or more portions of the exposed surface that are directly coupled to the interconnect 123. For example, the land pad 130 may have at least first and second portions that are directly attached and electrically coupled to a footprint 122 of a connector (or the like) of the interconnect 123. As such, in some embodiments, the interconnect 123 may be electrically coupled to at least a first portion of the land pad 130, and a portion of an inner gap 107 and/or the outer gap 109. Particularly, in some embodiments, the interconnect 123 may be electrically coupled to at least a first portion of the land pad 130, a second portion of the land pad 130, and a portion of the inner gap 107 and/or the outer gap 109, where the second portion may be spaced away from the first portion of the land pad 130 by the portion of the inner gap 107 and/or outer gap 109. Accordingly, in the illustrated embodiment, the first and second portions of the land pad 130 and the portion of the inner gap 107 (and the portion of the outer gap 109) are all positioned within the footprint 122 of the interconnect 123. For example, the first and second portions may be the illustrated portions on the left-side of the land pad 130 (i.e., the two corner edges on the left-side of the land pad 130) that are within the footprint 122 and spaced apart by the inner gap 107.

In one embodiment, the land pad 130 is an LGA land pad. In other embodiments, the land pad 130 may be any type of land pads. For example, the land pad 130 may be ball grid array (BGA) pads, land grid array (LGA) pads, pin grid array (PGA) pads, or the like. In an embodiment, the land pad 130 is a closed loop with an inner gap 107. Accordingly, the inner gap 107 allows the land pad 130 to have an outer perimeter and an inner perimeter that is opposite to the outer perimeter. That is, the land pad 130 is directly sandwiched between the outer gap 109 and the inner gap 107. In particular, the outer perimeter of the land pad 130 directly interfaces with the outer gap 109, while the inner perimeter of the land pad 130 directly interfaces with the inner gap 107.

Furthermore, in the illustrated embodiment, the land pad 130 may have a width S₁ that spaces away one portion of the outer perimeter from another portion of the outer perimeter. Likewise, in the illustrated embodiment, the land pad 130 may have a width S₂ that spaces away one portion of the inner perimeter from another portion of the inner perimeter. Also, as shown in the illustrated embodiment, the outer perimeter of the land pad 130 is positioned entirely within a footprint 110 that defines the maximum (or outermost) possible contact area for the interconnect 123. In an embodiment, the footprint 110 is spaced away from the land pad opening 105 by a width S₃ that serves as a land pad void region. In an embodiment, the widths S₁, S₂, and S₃ may be greater than approximately 20 μm. In some embodiments, the widths S₁, S₂, and S₃ may be between approximately 20 μm and 60 μm. In other embodiments, the widths S₁, S₂, and S₃ may be less than approximately 20 μm depending on substrate design rules. In one embodiment, the widths S₁, S₂, and S₃ may all be substantially equal to each other. In other embodiments, one or more of the widths S₁, S₂, and S₃ may be different from the other widths.

In one embodiment, the inner gap 107 may comprise fingers that are directly surrounded by the inner perimeter of the land pad 130. Additionally, in accordance with an embodiment, the inner gap 107 may be filled with a dielectric material—similar to the outer gap 109 disclosed above. In one embodiment, the inner and outer gaps 107 and 109 may comprise the same dielectric materials or different dielectric materials. The dielectric material of the inner gap 107 may have a surface that is substantially coplanar with the surfaces of the outer gap 109 and the land pad 130.

In one embodiment, the land pad 130 may comprise a conductive line 131 that is patterned into (or to form) the closed loop of the land pad 130. That is, since existing LGA land pads are patterned (or shaped) into rectangular pads, circular pads, oval pads, or the like, the land pad 130 is patterned into the closed loop using the conductive line 131. For example, the closed loop is routed with the conductive line 131 to occupy as much possible contact area within the footprint 110 by using line spacing(s) (e.g., the spacings S₁, S₂, and W) that is/are smaller than the footprint 122 of the nominal contact area of the interconnect 123 to thereby ensure proper electrical connection between the land pad 130 and the interconnect 123.

In an embodiment, the conductive line 131 is a continuous line (or an unbroken trace) that extends from a first end to a second end that is opposite to the first end. In some embodiments, the conductive line 131 is a serpentine line or the like. That is, in one embodiment, the conductive line 131 is patterned into a serpentine-shaped line that is interdigitated with the fingers of the inner gap 107. In other embodiments, the conductive line 131 may be any type of line with any type of shapes. In an embodiment, the conductive line 131 comprises a conductive material such as copper or the like.

Particularly, in some embodiments, the conductive line 131 serves as a type of transmission line for the land pad 130. For example, the conductive line 131 may be positioned entirely within the footprint 110 and patterned into the illustrated closed-loop transmission line that continuously extends between a via 112 and the footprint 122 of the interconnect 123. In an embodiment, the via 112 may be a microvia or the like that electrically couples the land pad 130 in the base layer 108 to an adjacent conductive layer.

Since the conductive line 131 continuously extends from one end to another opposite end (e.g., the ends respectively on the left and right sides of the via 112) in the closed loop in order to provide transmission-like properties for the land pad 130, there is substantially no lumped C effect with the land pad 130 in series with the interconnect 123. For example, the land pad 130 may present a minimum inductive effect. However, the minimum inductive effect can be substantially mitigated by adjusting the widths, bends, and spacings of the conductive line 131 in order to mimic transmission line behavior (i.e., the closed-loop transmission line disclosed above), which thereby allows the land pad 130 to provide substantially no parasitic impact to the high speed channels. As such, the land pad 130 may eliminate the lumped C effect to scale PCIe channels, DDR channels, or any other high speed channels, and enables both the return loss and insertion loss of such high speed channels to be improved at high frequencies. Accordingly, there is no need to reduce the land pad size nor use aggressive voiding around the land pads that negatively impact the electrical connections between the electronic package 100, the interconnect 123 of the socket, and/or any additional electronic components.

The conductive line 131 has the width W that is defined between the outer perimeter and the inner perimeter of the land pad 130. In an embodiment, the width W may be a uniform width that may be greater than approximately 20 μm. In some embodiments, the width W may be between approximately 20 μm and 60 μm. In other embodiments, the width W may be less than 20 μm depending on substrate design rules. In another embodiment, the width W may have one or more different widths that are between approximately 20 μm and 60 μm, or less than approximately 60 μm. In an embodiment, the conductive line 131 may have a length. For example, the length may be greater than approximately 2 mm. In some embodiments, the length may be between approximately 2 mm and 5 mm. In other embodiments, the length may be less than approximately 2 mm depending on substrate design rules.

Note that the electronic package 100 may include fewer or additional packaging components based on the desired packaging design.

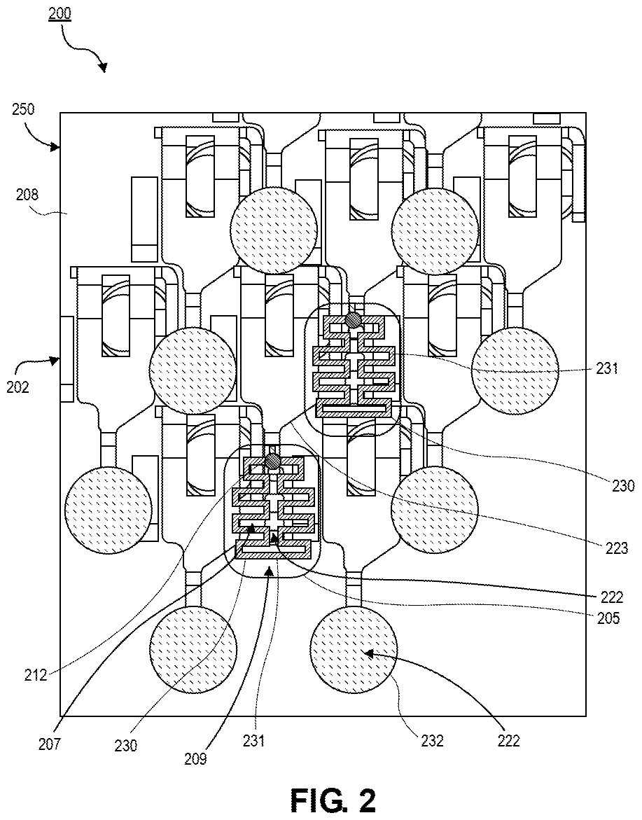

Referring now to FIG. 2, a plan illustration of an electronic packaged assembly 200 is shown, in accordance with an additional embodiment. In an embodiment, the electronic packaged assembly 200 comprises an electronic package 250 and a socket 202. In the illustrated embodiment, the electronic package 250 has a base layer 208 with a plurality of land pads 230 and 232 directly disposed over the socket 202. In an embodiment, the socket 202 may be any type of socket. In one embodiment, the socket 202 is an LGA socket. Particularly, in an embodiment, the electronic package 250 is electrically coupled to the socket 202 by a plurality of interconnects 223. In an embodiment, the interconnects 223 may comprise connectors 222 that are directly coupled to the respective land pads 230 and 232.

In an embodiment, the electronic package 250 may be substantially similar to the electronic package 100 in FIG. 1, with the exception that the land pads 232 may be grounded pads, and the land pads 230 are a differential pair of closed-loop pads with conductive lines 231 that are implemented with transmission line-like properties as disclosed above. As such, in one embodiment, the land pads 230 with land pad openings 205, inner and outer gaps 207 and 209, vias 212, and conductive lines 231 may be substantially similar to the land pads 130 with land pad openings 105, inner and outer gaps 107 and 109, vias 112, and conductive lines 131 in FIG. 1. In some embodiments, the land pads 230 may be paired as differential signal nets, and may be respectively coupled to the interconnects 223 that transmit differential signals. However, it is to be appreciated that any type of interconnects and signals may be coupled to the land pads 230 of the electronic package 250. Also, while only two land pads 230 are shown in FIG. 2, it is to be appreciated that embodiments may include any number of land pads 230.

Note that the electronic packaged assembly 200 may include fewer or additional packaging components based on the desired packaging design.

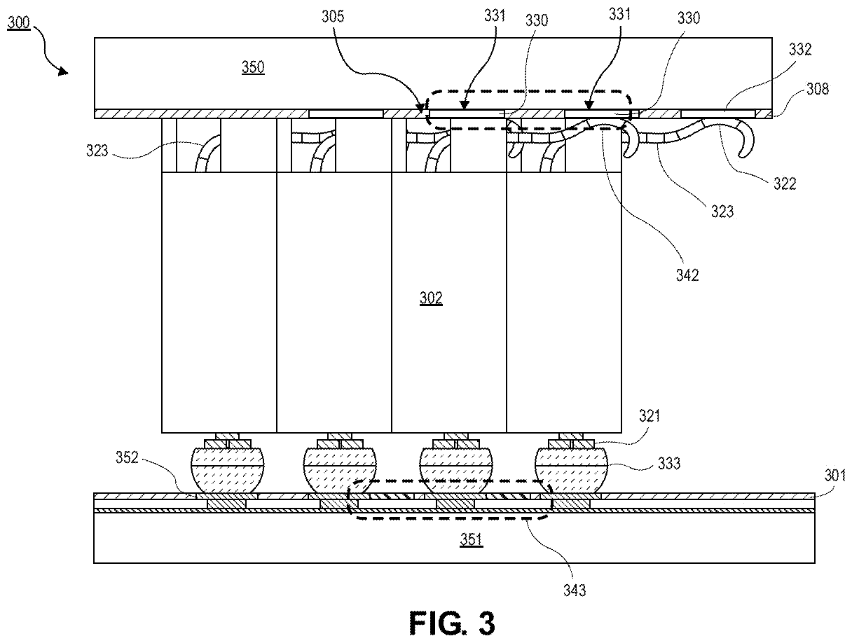

Referring now to FIG. 3, a cross-sectional illustration of an electronic packaged assembly 300 is shown, in accordance with an additional embodiment. In an embodiment, the electronic packaged assembly 300 comprises an electronic package 350, a socket 302, and a board 351. In an embodiment, the electronic packaged assembly 300 may be substantially similar to the electronic packaged assembly 200 in FIG. 2, with the exception that the socket 302 may be directly and electrically coupled to a board 351. In an embodiment, the board 351 may be a printed circuit board (PCB), a mother board, a substrate, or the like.

In some embodiments, the socket 302 may electrically couple the electronic package 350 to the board 351 by interconnects 323. In the illustrated embodiment, the electronic package 350 has a base layer 308 with land pads 330 and 332 that are directly disposed over the interconnects 323 of the socket 302. Particularly, the land pads 330 and 332 are directly coupled to connectors 322 of the interconnects 323.

In an embodiment, the electronic package 350 may be substantially similar to the electronic packages 100 and 250 in FIGS. 1-2. As such, in some embodiments, the land pads 330 with land pad openings 305 and conductive lines 331 may be substantially similar to the land pads 130 with land pad openings 105 and conductive lines 131 in FIG. 1. In the illustrated embodiments, the land pads 330 may be differential signal nets directly coupled to the respective interconnects 323 in order to transmit differential signals between a first port 342 in the electronic package 350 and a second port 343 in the board 351.

The board 351 may comprise a conductive layer 301 with conductive pads 352. In one embodiment, the board 351 may be directly coupled to the socket 302 by solder balls 333 or the like. That is, in some embodiments, the conductive pads 352 of the board 351 may be directly coupled to conductive pads 321 (or second connectors) of the interconnects 323 with the solder balls 333. Also, while only two land pads 330 and ports 342-343 are shown in FIG. 3, it is to be appreciated that embodiments may include any number of land pads 330 and ports 342-343.

Note that the electronic packaged assembly 300 may include fewer or additional packaging components based on the desired packaging design.

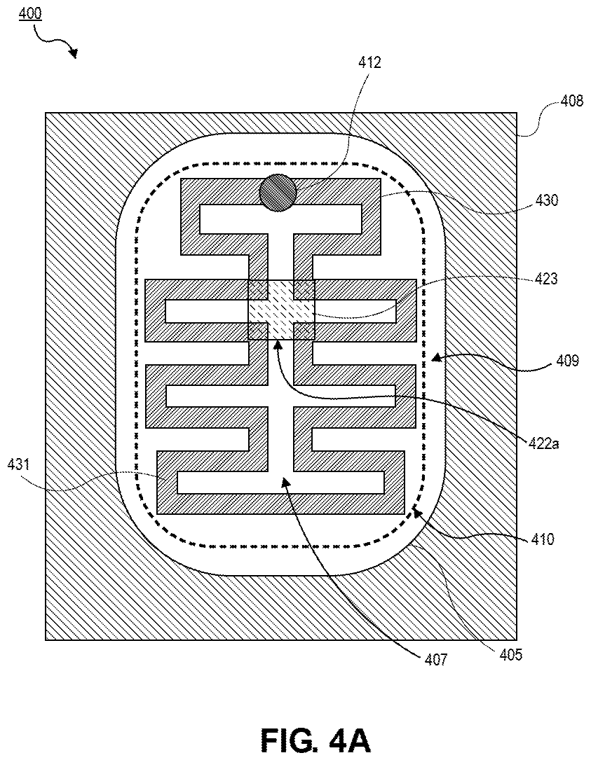

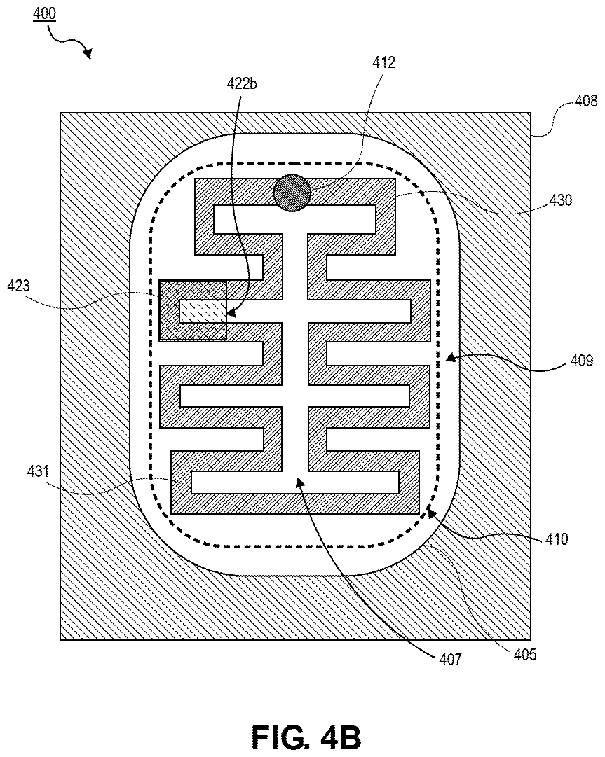

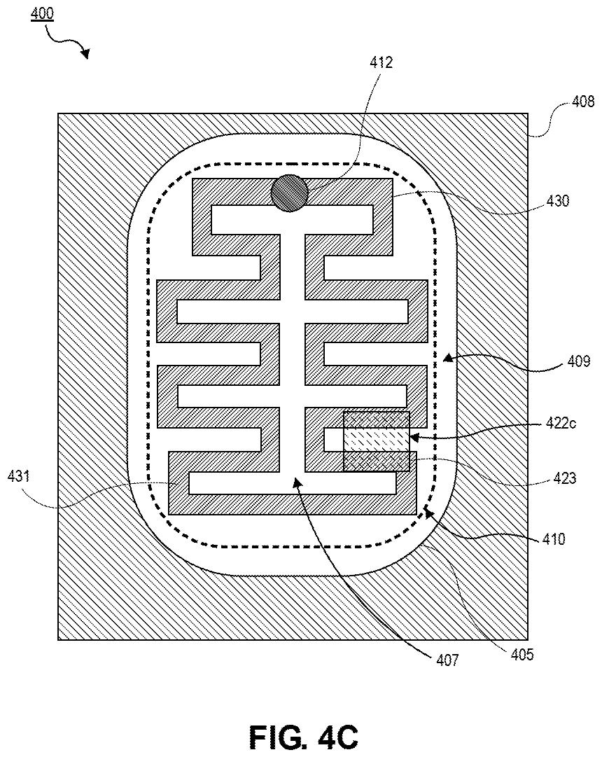

Referring now to FIGS. 4A-4C, a series of plan illustrations of an electronic package 400 are shown, in accordance with some embodiments. In an embodiment, the electronic package 400 in FIGS. 4A-4C may be substantially similar to the electronic package 100 in FIG. 1, with the exception that the interconnect 423 may have three different footprints 422a-c respectively positioned on three different contact locations of the land pad 430. As such, in some embodiments, the base layer 408, the interconnect 423, and the land pad 430 with land pad opening 405, inner and outer gaps 407 and 409, via 412, and conductive line 431 in the FIGS. 4A-4C may be substantially similar to the base layer 108, the interconnect 123, and the land pad 130 with land pad opening 105, inner and outer gaps 107 and 109, via 112, and conductive line 131 in FIG. 1.

In the illustrated embodiments, since all the area enclosed by the footprint 410 (as shown with the dashed lines) is possible contact locations for the interconnect 423, the land pad 430 may be coupled to the interconnect 423 respectively at such different footprints 422a-c as shown in FIGS. 4A-4C. In an embodiment, the different contact locations may have very minor impact on the reflection and the loss of the interconnect 423 and on the land pad 430 itself. Whereas, in some embodiments, the land pad 430 may have a more reduced lumped C effect when the footprint of the interconnect 423 is farther from via 412 (e.g., as shown with the footprint 422c in FIG. 4C compared to the other possible footprints 422a-b in FIGS. 4A-4B). Also, while three different footprint locations are shown in FIGS. 4A-4C, it is to be appreciated that embodiments may include any possible footprint locations on the land pad 430 enclosed by the envelop 410.

Note that the electronic package 400 may include fewer or additional packaging components based on the desired packaging design.

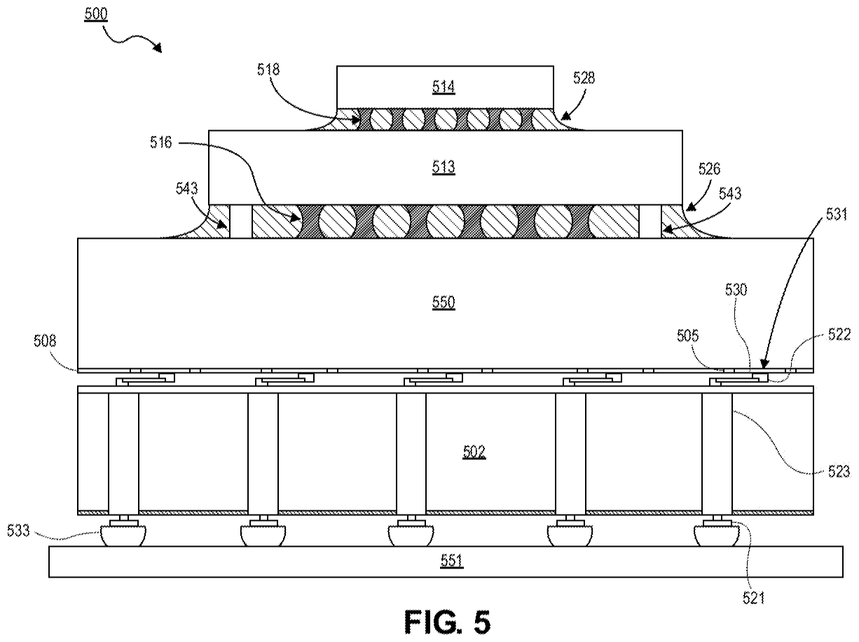

Referring now to FIG. 5, a cross-sectional illustration of an electronic packaged assembly 500 (or an electronic packaged system) is shown, in accordance with an embodiment. In an embodiment, the electronic packaged assembly 500 may comprise an electronic package 550 that is similar to the electronic package 100 in FIG. 1. For example, the electronic package 550 may have a base layer 508 that has land pad openings 505 and land pads 530. Also, in an embodiment, the land pad 530 may have a conductive line 531 that is patterned directly into a closed loop as shown in the land pad 130 in FIG. 1.

For some embodiments, the electronic packaged assembly 500 may include a die 514, a substrate 513, an electronic package 550, a socket 502, and a board 551, according to one embodiment. As shown in FIG. 5, in one embodiment, the electronic packaged assembly 500 may include the die 514 disposed on the substrate 513 (or an interposer), and the stack of die 514 and substrate 513 respectively disposed on the electronic package 550. In addition, for some embodiments, the semiconductor packaged assembly 500 may include the socket 502 to electrically couple the electronic package 550 to the board 551. In an embodiment, the connectors 522 of the interconnects 523 may be used to couple the socket 502 directly to the land pads 530 of the electronic package 550, while the connectors 521 of the interconnects 523 may be used to couple the socket 502 directly to the board 551 by the solder balls 533. As described above, in some embodiments, the land pads 530 may be patterned with the conductive lines 531 in the form of closed-loop transmission lines to suppress the land pad lumped C effect, to scale the PCIe and DDR speeds (e.g., PCIe generation 5/6 speeds and so on), and to significantly reduce the need for socket pad size reductions and/or aggressive package voiding.

In these embodiments, the electronic package 550, the socket 502, and the board 551 may be substantially similar to the electronic package 350, the socket 302, and the board 351 in FIG. 3. Also, in an embodiment, the interconnects 523 and the land pads 530 with land openings 505 and conductive lines 531 may be substantially similar to the interconnects 123 and the land pads 130 with land openings 105 and conductive lines 131 in FIG. 1. Note that the semiconductor packaged assembly 500 is not limited to the illustrated assembly/system, and thus may be designed/formed with fewer, alternate, or additional packaging components and/or with different interconnecting structures.

According to one embodiment, the electronic packaged assembly 500 is merely one example of an embodiment of an electronic packaged assembly (or system). For one embodiment, the electronic packaged assembly 500 may include a BGA package, a LGA package, and/or a PGA package. For one embodiment, the die 514 is coupled to the substrate 513 (e.g., an interposer) via one or more solder balls 518 (or bumps/joints) formed from respective microbumps, and the substrate 513 is coupled to the electronic package 550 via one or more solder balls 516 formed from respective microbumps. As described above, a solder ball formed by soldering of a microbump according to an embodiment may itself be referred to as a “bump” and/or a “microbump.” Additionally, one or more of the die 514, the substrate 513, the electronic package 550, and the board 551 may be coupled using an anisotropic conductive film (ACF) or the like. For one embodiment, the substrate 513 may be, but is not limited to, a silicon interposer and/or a die with through silicon vias (TSVs). For an alternate embodiment, the semiconductor packaged assembly 500 may omit the interposer/substrate 513.

The electronic package 550 may include a variety of electronic structures formed thereon or therein. In certain embodiments, the electronic packaged assembly 500 may be an organic substrate made up of one or more layers of polymer base materials or ceramic base materials, with conducting regions for transmitting signals. For some embodiments, the electronic packaged assembly 500 may include, but is not limited to, a package, a substrate, a PCB, a central processing unit (CPU) package substrate, and a motherboard. In one embodiment, the electronic package 550 is a PCB and/or a CPU package substrate (or an electronic package substrate), while the board 551 is a mother board. For one embodiment, the electronic package 550 is made of an FR-4 glass epoxy base with thin copper foil laminated on both sides. For certain embodiments, a multilayer electronic package 550 can be used, with pre-preg and copper foil used to make additional layers. For example, the multilayer electronic package 550 may include one or more dielectric layers. For one embodiment, the electronic package 550 may also include one or more conductive layers, which may further include copper (or metallic) traces, lines, pads, vias, holes, and/or planes.

For one embodiment, the die 514 may be comprised, but are not limited to, a semiconductor die, an electronic device (e.g., a wireless device), an IC, a CPU, a graphic processing unit (GPU), a microprocessor, a platform controller hub (PCH), a memory (e.g., a high bandwidth memory (HBM)), and/or a field-programmable gate array (FPGA). Additionally, in other embodiments, the die 514, the substrate 513, and/or the electronic package 550 may be comprised of one or more materials, including glass, crystal, diamond, low thermal conductive materials, high thermal conductive materials (e.g., gallium nitride (GaN) or the like), silicon, glass-based materials, and/or silicon-based materials (e.g., silicon carbide (SiC) or the like). Also, in other embodiments, the die 514 may be a plurality of chiplet dies. The die 514, the substrate 513, and/or the electronic package 550 may be formed from a material such as silicon and have circuitry thereon that is to be coupled to the each other and/or to any other electronic devices.

Although some embodiments are not limited in this regard, the board 551 may in turn be coupled to another body. One or more connections between one or more of the die 514, the substrate 513, the electronic package 550, the socket 502, and the board 551—e.g., including some or all of bumps 516, 518, and 533—may include one or more interconnect structures and underfill layers 526 and 528. In some embodiments, these interconnect structures (or connections) may variously comprise an alloy of nickel, palladium, and tin (and, in some embodiments, copper).

Connections between one or more of the die 514, the substrate 513, the electronic package 550, the socket, and the board 551 may be made using any suitable structure, such as the illustrative bumps 516, 518, and 533 shown. Although some embodiments are not limited in this regard, the electronic packaged assembly 500 may include gap control structures 543—e.g., positioned between the die 514, the substrate 513, and the electronic package 550. Such gap control structures 543 may mitigate a change in the height of the gap between the die 514, the substrate 513, and the electronic package 550. Note that the electronic packaged assembly 500 includes the underfill material 528 between the die 514 and the substrate 513, and the underflow material 526 between the substrate 513 and the electronic package 550. Also note that the underfill material may be disposed between any other components if desired. For one embodiment, the underfill materials (or layers) 526 and 528 may be one or more polymers that are injected between the layers. For other embodiments, the underfill materials may be molded underfill (MUF).

Note that the electronic packaged assembly 500 may include fewer or additional packaging components based on the desired packaging design.

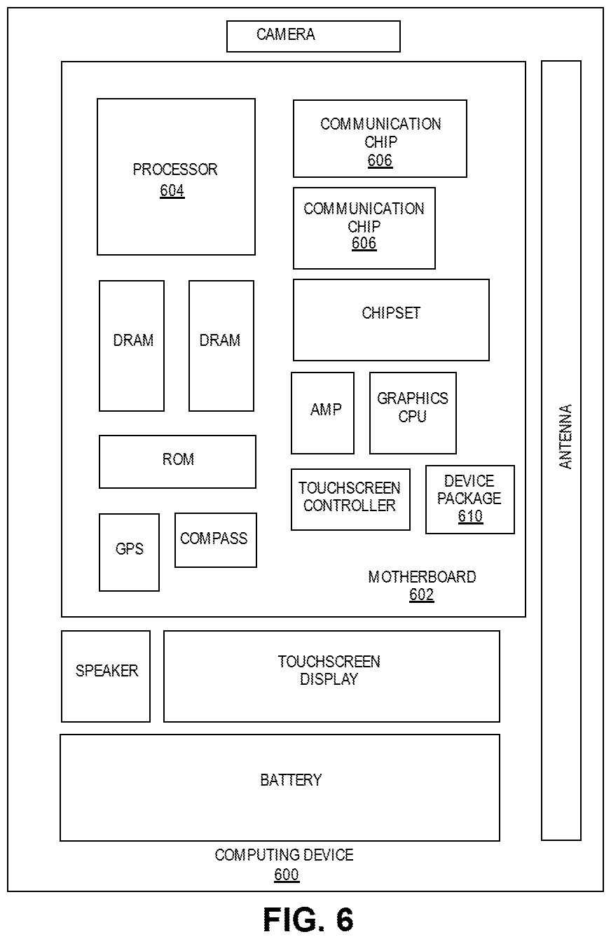

FIG. 6 illustrates a computing device 600 in accordance with one implementation of the invention. FIG. 6 illustrates an example of computing device 600. Computing device 600 houses a motherboard 602. Motherboard 602 may include a number of components, including but not limited to processor 604, device package 610 (or electronic package), and at least one communication chip 606. Processor 604 is physically and electrically coupled to motherboard 602. For some embodiments, at least one communication chip 606 is also physically and electrically coupled to motherboard 602. For other embodiments, at least one communication chip 606 is part of processor 604.

Depending on its applications, computing device 600 may include other components that may or may not be physically and electrically coupled to motherboard 602. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

At least one communication chip 606 enables wireless communications for the transfer of data to and from computing device 600. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. At least one communication chip 606 may implement any of a number of wireless standards or protocols, including but not limited to Wi-Fi (IEEE 802.11 family), WiMAX (IEEE 802.112 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. Computing device 600 may include a plurality of communication chips 606. For instance, a first communication chip 606 may be dedicated to shorter range wireless communications such as Wi-Fi and Bluetooth and a second communication chip 606 may be dedicated to longer range wireless communications such as GPS, EDGE, GPRS, CDMA, WiMAX, LTE, Ev-DO, and others.

Processor 604 of computing device 600 includes an integrated circuit die packaged within processor 604. The term “processor” may refer to any device or portion of a device that processes electronic data from registers and/or memory to transform that electronic data into other electronic data that may be stored in registers and/or memory. Device package 610 may be an electronic package. In one embodiment, device package 610 may be substantially similar to the electronic package 100 in FIG. 1. Device package 610 may include land pads having conductive lines directly that are patterned into closed loops (or closed-loop transmission lines) as described herein (e.g., as illustrated and described above with the land pads in FIGS. 1-3, 4A-4C, and 5)—or any other components from the figures described herein.

Note that device package 610 may be a single component/device, a subset of components, and/or an entire system, as the materials, features, and components may be limited to device package 610 and/or any other component of the computing device 600 that may need the lands pads with closed-loop transmission lines as described herein (e.g., the motherboard 602, the processor 604, the communication chips 606, and/or any other component of the computing device 600 that may need the embodiments described herein).

At least one communication chip 606 also includes an integrated circuit die packaged within the communication chip 606. For some embodiments, the integrated circuit die of the communication chip 606 may be packaged with one or more devices on an electronic package that includes one or more land pads with closed-loop transmission lines, as described herein.

In the foregoing specification, embodiments have been described with reference to specific exemplary embodiments thereof. It should be borne in mind, however, that all of these and similar terms are to be associated with the appropriate physical quantities and are merely convenient labels applied to these quantities. It will be evident that various modifications may be made thereto without departing from the broader spirit and scope. The specification and drawings are, accordingly, to be regarded in an illustrative sense rather than a restrictive sense.

The following examples pertain to further embodiments. The various features of the different embodiments may be variously combined with some features included and others excluded to suit a variety of different applications.

The following examples pertain to further embodiments:

Example 1: an assembly, comprising: a socket having an interconnect, wherein the interconnect has a first connector and a second connector opposite from the first connector; and an electronic package over the socket, wherein the electronic package comprises a first surface and a second surface that is opposite to the first surface, wherein the second surface has a land pad in a land pad opening, wherein the land pad is spaced away from the land pad opening by an outer gap, wherein the land pad is a closed loop with an inner gap, wherein the closed loop is directly between the outer gap and the inner gap, and wherein the first connector of the interconnect is electrically coupled to at least a portion of the closed loop and a portion of the inner or outer gap.

Example 2: the assembly of Example 1, wherein the first connector of the interconnect is also electrically coupled to a second portion of the closed loop, and wherein the second portion is spaced away from the portion of the closed loop by the portion of the inner or outer gap.

Example 3: the assembly of Examples 1-2, wherein the closed loop has an outer perimeter and an inner perimeter.

Example 4: the assembly of Examples 1-3, wherein the outer perimeter directly interfaces with the outer gap, and wherein the inner perimeter directly interfaces with the inner gap.

Example 5: the assembly of Examples 1-4, wherein the closed loop of the land pad is electrically coupled to the first connector of the interconnect.

Example 6: the assembly of Examples 1-5, wherein the closed loop comprises a conductive line that has a first end and a second end that is opposite to the first end, and wherein the conductive line continuously extends from the first end to the second end.

Example 7: the assembly of Examples 1-6, further comprising: a conductive layer electrically coupled to the closed loop of the land pad by a via, wherein the conductive layer is positioned above the second surface, and wherein the first and second ends of the conductive line are directly coupled to the via; a die electrically coupled to the electronic package, wherein the die is over the first surface of the electronic package, and wherein the second surface of the electronic package is over the board; and a board electrically coupled to the socket, wherein the second connector of the interconnect is coupled to the board.

Example 8: the assembly of Examples 1-7, wherein the portion and the second portion of the closed loop are within a footprint of the first connector, and wherein the portion of the inner or outer gap is also within the footprint of the first connector.

Example 9: the assembly of Examples 1-8, wherein the conductive line is a serpentine line.

Example 10: a package substrate, comprising: a substrate having a first surface and a second surface opposite from the first surface; a plurality of land openings in the second surface; and a plurality of land pads in the second surface, wherein each of the land pads is in one of the land pad openings, wherein each of the land pads is spaced away from the respective land pad openings by an outer gap, wherein each of the land pads is a closed loop with an inner gap, wherein the closed loop is directly between the outer gap and the inner gap, wherein the closed loop comprises a conductive line that has a first end and a second end that is opposite to the first end, and wherein the conductive line continuously extends from the first end to the second end.

Example 11: the package substrate of Example 10, wherein the closed loop has an outer perimeter and an inner perimeter, wherein the outer perimeter directly interfaces with the outer gap, and wherein the inner perimeter directly interfaces with the inner gap.

Example 12: the package substrate of Examples 10-11, further comprising: a conductive layer electrically coupled to the closed loop of the land pad by a via, wherein the conductive layer is positioned above the second surface, and wherein the first and second ends of the conductive line are directly coupled to the via; and an interconnect having a connector, wherein the connector is directly below the closed loop.

Example 13: the package substrate of Examples 10-12, wherein the connector of the interconnect is electrically coupled to at least a first portion of the closed loop and a portion of the inner or outer gap.

Example 14: the package substrate of Examples 10-13, wherein the connector of the interconnect is also electrically coupled to a second portion of the closed loop, and wherein the second portion is spaced away from the first portion by the portion of the inner or outer gap.

Example 15: the package substrate of Examples 10-14, wherein the first and second portions of the closed loop are within a footprint of the connector, and wherein the portion of the inner or outer gap is also within the footprint of the connector.

Example 16: the package substrate of Examples 10-15, wherein the conductive line is a serpentine line.

Example 17: an electronic packaged assembly, comprising: a board; a socket electrically coupled to the board, wherein the socket has a plurality of interconnects, and wherein each of the interconnects has a first connector and a second connector opposite from the first connector; an electronic package electrically coupled to the socket, the electronic package comprises a first surface and a second surface that is opposite to the first surface, wherein the second surface has a plurality of land pad openings and a plurality of land pads, wherein each land pad is in one of the land pad openings, wherein each land pad is spaced away from the respective land pad opening by an outer gap, wherein each land pad is a closed loop, wherein the closed loop is directly between the outer gap and the inner gap, and wherein the first connector of the interconnect is electrically coupled to at least a first portion of the closed loop, a second portion of the closed loop, and a portion of the inner or outer gap; and a die electrically coupled to the electronic package.

Example 18: the electronic packaged assembly of Example 17, wherein the second portion is spaced away from the first portion by the portion of the inner or outer gap.

Example 19: the electronic packaged assembly of Examples 17-18, wherein the closed loop of the land pad is electrically coupled to the first connector of the interconnect, wherein the die is over the first surface of the electronic package, wherein the second surface of the electronic package is over the board, and wherein the second connector of the interconnect is coupled to the board.

Example 20: the electronic packaged assembly of Examples 17-19, wherein the closed loop comprises a conductive line that has a first end and a second end that is opposite to the first end, and wherein the conductive line continuously extends from the first end to the second end.

Example 21: the electronic packaged assembly of Examples 17-20, wherein the closed loop has an outer perimeter and an inner perimeter.

Example 22: the electronic packaged assembly of Examples 17-21, wherein the outer perimeter directly interfaces with the outer gap, and wherein the inner perimeter directly interfaces with the inner gap.

Example 23: the electronic packaged assembly of Examples 17-22, further comprising: a conductive layer electrically coupled to the closed loop of the land pad by a via, wherein the conductive layer is positioned above the second surface of the electronic package, and wherein the first and second ends of the conductive line are directly coupled to the via.

Example 24: the electronic packaged assembly of Examples 17-23, wherein the first and second portions of the closed loop are within a footprint of the first connector, and wherein the portion of the inner or outer gap is also within the footprint of the first connector.

Example 25: the electronic packaged assembly of Examples 17-24, wherein the conductive line is a serpentine line.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

In the foregoing specification, methods and apparatuses have been described with reference to specific exemplary embodiments thereof. It will be evident that various modifications may be made thereto without departing from the broader spirit and scope. The specification and drawings are, accordingly, to be regarded in an illustrative sense rather than a restrictive sense.

What is claimed is:

1. An assembly, comprising:
a socket having an interconnect, wherein the interconnect has a first connector and a second connector that is opposite from the first connector; and
an electronic package over the socket, wherein the electronic package comprises a first surface and a second surface that is opposite to the first surface, wherein the second surface has a land pad in a land pad opening, wherein the land pad is spaced away from the land pad opening by an outer gap, wherein the land pad is a closed loop with an inner gap, wherein the closed loop is directly between the outer gap and the inner gap, and wherein the first connector of the interconnect is electrically coupled to at least a portion of the closed loop and a portion of the inner or outer gap.

2. The assembly of claim 1, wherein the first connector of the interconnect is also electrically coupled to a second portion of the closed loop, and wherein the second portion is spaced away from the portion of the closed loop by the portion of the inner or outer gap.

3. The assembly of claim 1, wherein the closed loop has an outer perimeter and an inner perimeter.

4. The assembly of claim 3, wherein the outer perimeter directly interfaces with the outer gap, and wherein the inner perimeter directly interfaces with the inner gap.

5. The assembly of claim 1, wherein the closed loop of the land pad is electrically coupled to the first connector of the interconnect.

6. The assembly of claim 1, wherein the closed loop comprises a conductive line that has a first end and a second end that is opposite to the first end, and wherein the conductive line continuously extends from the first end to the second end.

7. The assembly of claim 4, further comprising:
a conductive layer electrically coupled to the closed loop of the land pad by a via, wherein the conductive layer is positioned above the second surface, and wherein the first and second ends of the conductive line are directly coupled to the via;
a die electrically coupled to the electronic package, wherein the die is over the first surface of the electronic package, and wherein the second surface of the electronic package is over the board; and
a board electrically coupled to the socket, wherein the second connector of the interconnect is coupled to the board.

8. The assembly of claim 7, wherein the portion and the second portion of the closed loop are within a footprint of the first connector, and wherein the portion of the inner or outer gap is also within the footprint of the first connector.

9. The assembly of claim 6, wherein the conductive line is a serpentine line.

10. A package substrate, comprising:
a substrate having a first surface and a second surface that is opposite from the first surface;
a plurality of land openings in the second surface; and
a plurality of land pads in the second surface, wherein each of the land pads is in one of the land pad openings, wherein each of the land pads is spaced away from the respective land pad openings by an outer gap, wherein each of the land pads is a closed loop with an inner gap, wherein the closed loop is directly between the outer gap and the inner gap, wherein the closed loop comprises a conductive line that has a first end and a second end that is opposite to the first end, and wherein the conductive line continuously extends from the first end to the second end.

11. The package substrate of claim 10, wherein the closed loop has an outer perimeter and an inner perimeter, wherein the outer perimeter directly interfaces with the outer gap, and wherein the inner perimeter directly interfaces with the inner gap.

12. The package substrate of claim 10, further comprising:
a conductive layer electrically coupled to the closed loop of the land pad by a via, wherein the conductive layer is positioned above the second surface, and wherein the first and second ends of the conductive line are directly coupled to the via; and
an interconnect having a connector, wherein the connector is directly below the closed loop.

13. The package substrate of claim 12, wherein the connector of the interconnect is electrically coupled to at least a first portion of the closed loop and a portion of the inner or outer gap.

14. The package substrate of claim 13, wherein the connector of the interconnect is also electrically coupled to a second portion of the closed loop, and wherein the second portion is spaced away from the first portion by the portion of the inner or outer gap.

15. The package substrate of claim 14, wherein the first and second portions of the closed loop are within a footprint of the connector, and wherein the portion of the inner or outer gap is also within the footprint of the connector.

16. The package substrate of claim 10, wherein the conductive line is a serpentine line

17. An electronic packaged assembly, comprising:
a board;
a socket electrically coupled to the board, wherein the socket has a plurality of interconnects, and wherein each of the interconnects has a first connector and a second connector that is opposite from the first connector;
an electronic package electrically coupled to the socket, the electronic package comprises a first surface and a second surface that is opposite to the first surface, wherein the second surface has a plurality of land pad openings and a plurality of land pads, wherein each land pad is in one of the land pad openings, wherein each land pad is spaced away from the respective land pad opening by an outer gap, wherein each land pad is a closed loop, wherein the closed loop is directly between the outer gap and the inner gap, and wherein the first connector of the interconnect is electrically coupled to at least a first portion of the closed loop, a second portion of the closed loop, and a portion of the inner or outer gap; and
a die electrically coupled to the electronic package.

18. The electronic packaged assembly of claim 17, wherein the second portion is spaced away from the first portion by the portion of the inner or outer gap.

19. The electronic packaged assembly of claim 17, wherein the closed loop of the land pad is electrically coupled to the first connector of the interconnect, wherein the die is over the first surface of the electronic package, wherein the second surface of the electronic package is over the board, and wherein the second connector of the interconnect is coupled to the board.

20. The electronic packaged assembly of claim 17, wherein the closed loop comprises a conductive line that has a first end and a second end that is opposite to the first end, and wherein the conductive line continuously extends from the first end to the second end.

21. The electronic packaged assembly of claim 17, wherein the closed loop has an outer perimeter and an inner perimeter.

22. The electronic packaged assembly of claim 21, wherein the outer perimeter directly interfaces with the outer gap, and wherein the inner perimeter directly interfaces with the inner gap.

23. The electronic packaged assembly of claim 20, further comprising:
a via electrically couples the closed loop of the land pad to a conductive layer, wherein the conductive layer is positioned above the base layer, and wherein the first and second ends of the conductive line are directly coupled to the via.

24. The electronic packaged assembly of claim 17, wherein the first and second portions of the closed loop are within a footprint of the first connector, and wherein the portion of the inner or outer gap is also within the footprint of the first connector.

25. The electronic packaged assembly of claim 20, wherein the conductive line is a serpentine line.
